(19) United States
(12) Patent Application Publication
(10) Pub. No.: US 2007/0030658 A1
(43) Pub. Date: Feb. 8, 2007

(54) Space saving rack mountable electronic component housing

(75) Inventors: Eugene K. Norgard, San Ramon, CA (US); Laurie A. Miille, Pleasanton, CA (US); Tom Hamski, North Omsted, OH (US)

Correspondence Address: LEYDIG VOIT & MAYER, LTD, TWO PRUDENTIAL PLAZA, SUITE 4900, 180 NORTH STETSON AVENUE, CHICAGO, IL, 60601-6731, US

(73) Assignee: Charles Industries, Ltd., Rolling Meadows, IL (US)

(21) Appl. No.: 11/388,702

(22) Filed: Mar. 24, 2006

Related U.S. Application Data
(60) Provisional application No. 60/664,915, filed on Mar. 24, 2005.

(51) Int. Cl. H05K 7/14

(52) U.S. Cl. 361/730; 361/796; 361/788

(57) ABSTRACT

An electronic component, particularly a multiplexer, having a housing that is configured to consume less space when stored in a vertical electronics rack is provided. The housing generally includes a rear end having a plurality of connectors and a front end, a bottom wall, a pair of laterally spaced side walls and a top wall. The top wall is configured such that a portion of the housing at the rear end of the multiplexer has a relatively larger height than the remainder of the housing.

### CROSS-REFERENCE TO RELATED APPLICATIONS

This patent application claims the benefit of U.S. Provisional Patent Application No. 60/664,915, filed Mar. 24, 2005.

### BACKGROUND OF THE INVENTION

In the telecommunications industry, a variety of electronic components are stored in vertical racks. Such vertical racks typically include a number of horizontally extending bays arranged one on top of another in a vertical array. In typical installations, each of the horizontal bays is adapted to receive an electronic component. One example of electronic components that are stored in such racks is broadband electrical and optical multiplexers.

In these racks, efficient use of space is a particular concern as it is generally desirable to store as many electronic components as possible in a given rack. In the case of multiplexers, many multiplexers are specifically designed to be stored in standard electronics racks. To fit on standard electronics racks, the multiplexers have to be limited to a height of 3½ inches. Because standard connectors require a space taller than 3½ inches, multiplexers designed to fit on standard electronic racks generally must use miniature connectors and custom cable assemblies to connect the multiplexer to the existing network.

However, such miniature connectors are not suitable for every application. In particular, standard connectors are required in some situations. Standard connectors are relatively taller than the miniaturized connectors (e.g., 5¼ inches in height). In order to accommodate the larger standard connectors, the multiplexer housings are sized relatively larger. Unfortunately, as a result of the larger housing, fewer multiplexers can be stored on each rack.

### BRIEF SUMMARY OF THE INVENTION

The invention provides an electronic component, particularly a multiplexer, having a housing that is configured to consume less space when stored in a vertical electronics rack. The housing generally includes a rear end having a plurality of connectors and a front end, a bottom wall, a pair of laterally spaced side walls and a top wall. The top wall of the housing is configured such that a portion of the housing at the rear end of the multiplexer has a relatively larger height than the remainder of the housing.

### BRIEF DESCRIPTION OF THE DRAWINGS

FIG. 1 is a front perspective view of an exemplary multiplexer having a housing according to the present invention.

FIG. 2 is a side view of the multiplexer of FIG. 1.

FIG. 3 is a rear view of the multiplexer of FIG. 1.

FIG. 4 is an exploded, perspective view of the multiplexer of FIG. 1.

FIG. 5 is a partial, perspective view of the multiplexer of FIG. 1 as installed in an illustrative electronics rack.

### DETAILED DESCRIPTION OF THE INVENTION

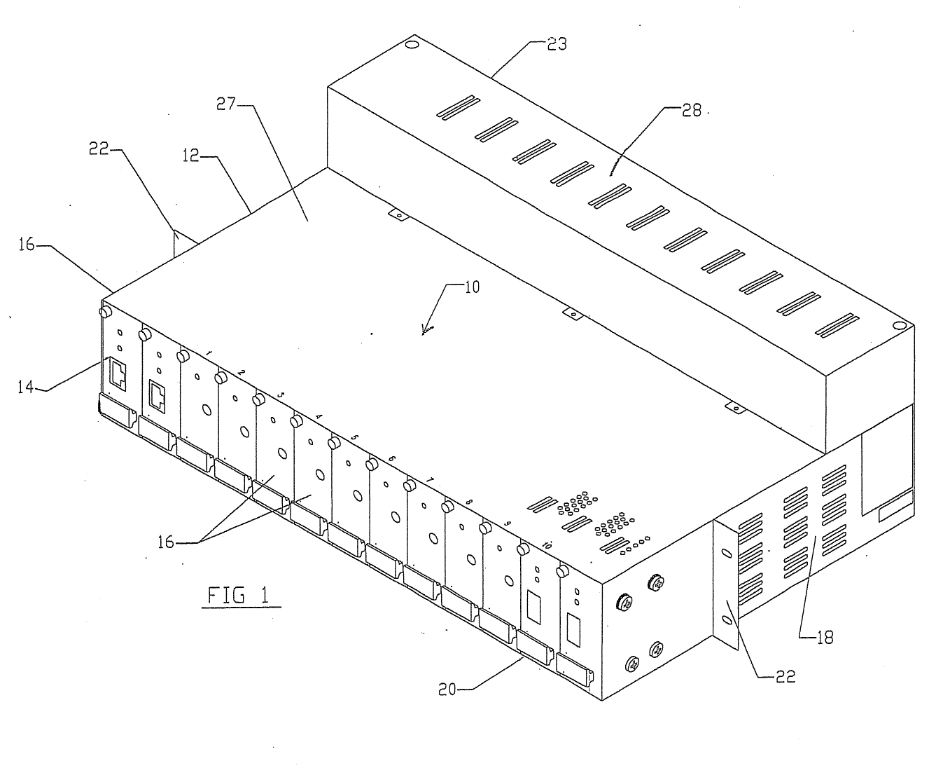

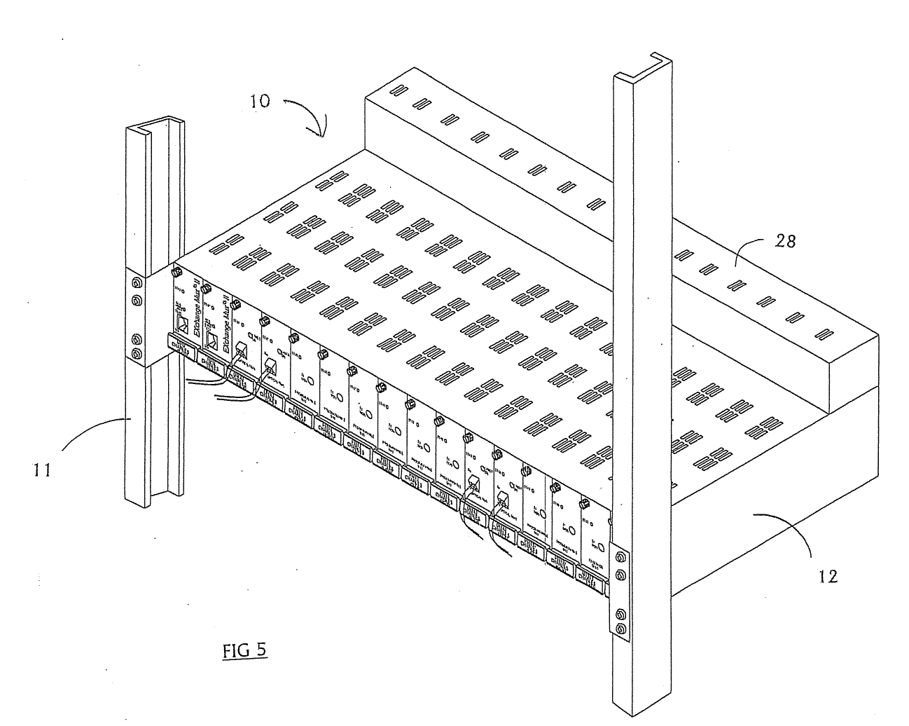

Referring now to FIG. 1 of the drawings, an exemplary multiplexer 10, in this case a broadband multiplexer, is shown which has a housing configured according to the present invention. The multiplexer is particularly designed for storage in a vertical rack 11 (see FIG. 5) that comprises a number of horizontal shelves or bays that are stacked one on top of another. Each shelf or bay in the rack defines a rectangular three-dimensional space that can accommodate a multiplexer unit. As will be understood by those skilled in the art from the following description, while the present invention is described in connection with a multiplexer, the invention is not limited to use only on multiplexers. To the contrary, the present invention can be applied in any electronic component storage context in which space savings in a vertical rack is desired.

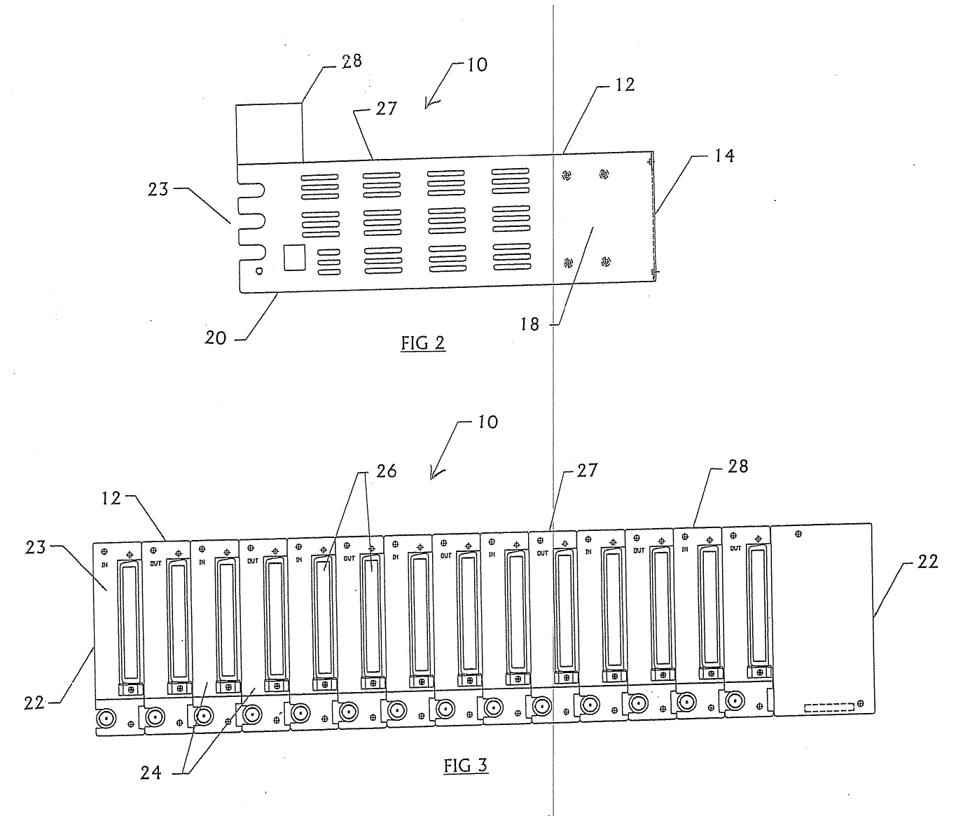

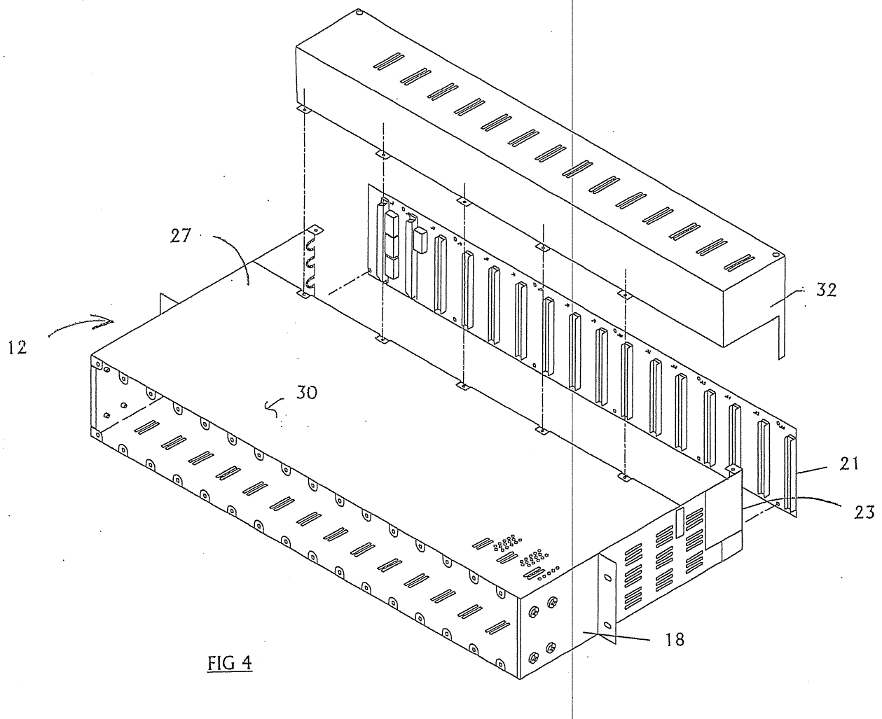

In the illustrated embodiment, the multiplexer includes a housing 12 having a front end 14 in which a number of multiplexing modules 16 are arranged in side-by-side relation. The multiplexer housing further includes a pair of laterally spaced sidewalls 18 and a bottom wall 20. In this instance, a laterally extending mounting bracket 22 is provided on each of the housing sidewalls 18. The rear end 23 of the multiplexer includes a backplane 21 (see FIG. 4) and a number of redundancy interface modules (RIMs) 24 (see FIG. 3) that are arranged in side-by-side relation. Each of the RIMs 24 includes a connector 26, in this instance a T1 connector receptacle.

The connectors 26 provided on the RIMs are standard-sized connectors. As compared to the miniaturized connectors provided on some multiplexers, these standard connectors 26 are taller (e.g., 5¼ inches as compared to 3½ inches). Conventional multiplexers having standard connectors include housings that have a larger height from front-to-back so as to maintain the rectilinear geometry that is commonly found on multiplexers and other rack mounted electronic components. To the extent cooling fans are required in order to keep the multiplexers cool, they must be provided in the rack bay above the multiplexer housing. Unfortunately, this consumes bays in the rack that otherwise could be used to store additional multiplexers.

The use of the larger standard connectors 26 generally does not require additional vertical space in the multiplexer housing all the way to the front of the housing. Thus, according to the present invention, the multiplexer housing 12 has a top wall 27 configured such that the height of the housing 12 is only increased in a rear portion 28 of the housing 12 so as to be able to accommodate the larger standard connectors 26 as shown in FIGS. 1, 3 and 5. The remainder of the multiplexer housing 12 has a height that is relatively lower than the height of the rear portion 28 of the housing. In this way, only the portion of the housing that needs the extra space to accommodate the larger standard connectors has a higher height profile.

Advantageously, using a stepped configuration for the top wall 27 of the multiplexer housing 12 with a relatively higher portion for the connectors 26 and a relatively lower portion for the remainder of the housing provides additional space above the multiplexer in each bay in an electronic storage rack (see, e.g., FIG. 5). This additional space can be used, for example, to provide supplemental cooling units for the multiplexer 10 such as cooling fans or air chambers. Thus, the housing 12 of the present invention allows supplemental cooling to be provided without using space in the electronics rack that could be used to store other multiplexers.

An additional advantage of the housing 12 of the present invention is that many of the same components used in the multiplexers having the miniaturized (e.g., 3½ inches tall) connectors can be used in the multiplexer having the standard connectors 26. For instance, the same main chassis 30 portion of the housing, service modules and backplane 21 can be used in the standard connector multiplexer as is used in the miniaturized connector multiplexer (see FIG. 4). A section 32 of the top wall 27 of the multiplexer housing 12 can also be designed so as to be removable so that the backplane 21 can be mounted first inside the housing as shown in FIG. 4. Once the backplane 21 is mounted in the housing, the removable section 32 of the top wall can be secured back in place.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A rack-mountable electronic component comprising:
a housing having a front wall, a backplane opposite the front wall, laterally spaced sidewalls, a bottom wall, and a top wall, the housing having a relatively greater height between the top wall and the bottom wall proximate the backplane than proximate the front wall.

2. The electronic component of claim 1, wherein the top wall has a stepped configuration for providing the relatively greater height.

3. The electronic component of claim 2, wherein the top wall includes a removable section providing the stepped configuration.

4. The electronic component of claim 1, wherein the height of the housing at the backplane is about 5.25 inches.

5. The electronic component of claim 1, wherein the height of the housing at the front wall is about 3.5 inches.

6. The electronic component of claim 1, wherein the electronic component is a multiplexer.

7. The electronic component of claim 1, wherein the backplane includes a plurality of connectors.

8. The electronic component of claim 7, wherein the connectors are T1 connectors.

9. A vertical electronics rack of electronic components comprising:
an vertical electronics rack of vertically arranged generally rectangular bays; and
a plurality of electronic components, each electronic component received in a bay, at least one electronic component including a housing having a front wall, a backplane opposite the front wall, laterally spaced sidewalls, a bottom wall, and a top wall, the housing having a relatively greater height between the top wall and the bottom wall proximate the backplane than proximate the front wall.

10. The electronics rack of claim 9, wherein the top wall of the at least one electronic component has a stepped configuration for providing the relatively greater height.

11. The electronics rack of claim 10, wherein the top wall of the at least one electronic component has a removable section providing the stepped configuration.

12. The electronics rack of claim 9, wherein space between the top wall of the at least one electronic component and the bottom wall of a vertically adjacent electronic component is greater proximate the front wall than proximate the back panel.

13. The electronics rack of claim 12, further comprising a cooling fan located in the space between the top wall of the at least one electronic component and the bottom wall of the vertically adjacent electronic component.
